(19) United States
(12) Patent Application Publication
(10) Pub. No.: US 2025/0174513 A1
(43) Pub. Date: May 29, 2025

(54) Diamond Wafer Based Electronic Component and Method of Manufacture

(71) Applicant: Diamond Foundary Incorporated, South San Francisco, CA (US)

(72) Inventor: Jean-Claude Harel, San Jose, CA (US)

(21) Appl. No.: 18/679,212

(22) Filed: May 30, 2024

Related U.S. Application Data
(63) Continuation of application No. PCT/US2022/050538, filed on Nov. 21, 2022.
(60) Provisional application No. 63/288,066, filed on Dec. 10, 2021.

(51) Int. Cl. H01L 23/373; H01L 21/48

(52) U.S. Cl. CPC H01L 23/3732; H01L 21/4803; H01L 23/3735

(57) ABSTRACT

An electronic component, intermediate stage of production and method of making, comprising a stack having a metallic substrate, a single crystal diamond (SCD) wafer, and a metallic layer is disclosed. A first sintered metal layer forms a bond between the substrate and the SCD wafer, and a second sintered metal layer forms a bond between the SCD wafer and the metallic layer. The metallic layer is thinner than the metallic substrate.

### BENEFIT OF PRIORITY

This U.S. Application is a continuation of International Application PCT/US2022/050538 filed on Nov. 21, 2022, the entire contents of which are incorporated herein by reference. International Application PCT/US2022/050538 claims the benefit of priority to U.S. Provisional Application 63/288,066 filed on Dec. 10, 2021, the entire contents of which are incorporated herein by reference.

### FIELD OF THE DISCLOSURE

Aspects of the present disclosure relate to substrates for semiconductor devices. Specifically, aspects of the present disclosure related to diamond substrates for semiconductor devices.

### BACKGROUND OF THE DISCLOSURE

### Advancing Energy Efficiency in EV Power Electronics

The large majority of power inverters architecture consists of converting the DC voltage from the battery to a 3-phase AC format compatible with the electric traction motor. Today power conversion ranges from 50 to 250 KW (400 kW peak) depending on models. Years to come will see the emergence of MW systems (trucking industry, naval transportation, and more importantly the aerial e-mobility). Each phase requires two power switches mounted in a so-called “half bridge” topology. During operation, because the three-phases are shifted at a 120-degree angle, always two switches are closed (ON) simultaneously, the other four being open (OFF).

In order to evaluate the inverter efficiency, conduction losses are calculated from the voltage difference when the switch is closed multiplied by the current flowing into the switch, of course multiplied by 6 (3×2=6 switches). The level of power losses generated is substantial, and designers always have tried to reduce it to increase driving range or battery size reduction. Some other considerations such as wire-bonds' stress and capacity, gate-drivers' performances and overall system size and cost are as well part of the equation when designing a power traction inverter. So far, the rule of thumb to reduce power losses has been to use more silicon surface area or use a better heat sink. Both approaches have significant drawbacks. Using more silicon switches reduces power conduction losses since the “ON” state current is shared among a greater number of switches therefore reducing the power to be dissipated. However, the switching losses increase accordingly especially with insulated gate bipolar transistors (IGBTs). The drawback is the exponential surface attachment to be used, the multiplication of weak links in the power path such as wire bonds, the disparity from die to die, the physical distance expansion leading to detrimental parasitic inductances and the difficulty of perfectly synchronizing each die to its companion die, eventually ending with an unnecessary complexity and poor efficiency for the effort deployed. Furthermore, cost considerations make this approach problematic.

Cooling strategy on the other hand has been a topic of experiments and research and development for many years. Rather than only focusing on silicon improvements, designers had a sense that reducing the operating temperature of the dies could be the path to power efficiency, cost reduction and greater reliability. Though that intuition is certainly correct, nowadays available materials to ensure a satisfying result is by far unreachable.

Because the electrical and thermal paths for power silicon are identical and both of substantial magnitude, it is extremely challenging to literally disconnect them to direct the thermal path to a liquid coolant that needs to be electrically isolated for safety reasons and the electrical path that needs to be as short and resilient as possible. That disconnection mechanism (the “dielectric”) is accomplished through techniques and technologies illustrated in FIGS. 1A-1C that have not really evolved significantly over the past four decades, achieving poor results despite being largely adopted.

FIG. 2 depicts a common architecture for a power device. Generally, the device includes a silicon die 201 that is attached by an attachment 202 to a copper layout 203, which is thermally coupled to a coolant 206 via a substrate 204 and dielectric material 205. Electric current flows mainly laterally in the copper layout 203 but mainly vertically from the die 201 through the attachment 202, layout 203, substrate 204 and dielectric 205. Such an architecture is characterized by relatively poor two-dimensional vectorial thermal propagation in the thermal path between the silicon die 201 and the coolant 206. For example, if the coolant 206 is at a temperature of about 80° C., the die 201 is typically at a temperature of 175-200° C. due to thermal impedance in the thermal path. The common architecture of FIG. 2 can be decomposed by the simplified thermal-impedance (Rth) model shown in FIG. 3A and summarized in the table shown FIG. 3B.

FIG. 3 shows that thermal impedance (Rth) between the die 201 and the coolant 206 is spread into three main categories:

1) Dielectric material 205 (Rth4): With a large range of performances and characteristics, dielectric materials must ensure the best thermal conductivity achieving automotive isolation requirements in the order of 4 kV for 1 minute, dictating the material thickness therefore Rth.

2) Substrates and mechatronics (Rth2, Rth6, Rth8): Substrates offer mechanical robustness and die mountability as well as exposed surfaces ensuring the thermal continuity to the coolant through the inverter system (mechatronics).

3) Surfaces junction is the point of junction of different elements mounted together and can be categorized in 3 main groups:
a) Soldering or sintering diffusion (Rth1) that offer the best thermal conductivity depending on the material used, interface thickness and thermal conductivity.
b) Deposition coating of ceramics to metal (e.g., Al2O3 flame spray coating) inducing an inter-material interface with its own Rth (Rth3, Rth5) depending of porosity and penetration;
c) Pressure contact (Rth7) where two surfaces are pressed together to create a thermal path (often the electric path too). This type of interface is highly dependent on the pressure applied, coplanarity, roughness and geometries of the surfaces. It is usually of poor performance and degrades with time.

Though non-intuitive, liquid to solid surface contact (Rth8) is part of this category but is more stable and of better quality/performance depending on the strategy adopted. Laminar flow on a planar surface exhibits a reduced efficiency since only a few molecules at the coolant surface contact to the solid surface will carry the calories to be extracted. The rest of the liquid does not participate actively in the cooling. Turbulent flow creates a greater surface contact area and more carriers but requires a special mechanism to be implemented leading to a greater use of material and system volume increases (i.e., thin fins). As seen above, the total junction to coolant Rth is more an agglomeration of material properties, techniques, and surface area than a single dimension issue. There is a substantial margin for progress.

Advancement in power inverters has been slow and incremental due to complex design and manufacturing aggravated by custom subsystems requirements, sophisticated integration of high-power electronics, material science, mechatronics, and thermal management. Power density is certainly the key metric of performance for modern power inverters underscoring technology and efficiency. As a reference, state-of-the-art designs exhibit 33 kW/L (Tesla Model 3 is 12L, 4.8 kg, 400 kW) and 36 kW/L (Audi e-Tron is 5.5L, 8 kg, 200 kW).

Power semiconductors are essentially driven by two factors: Thermal conductivity—the path to cool them down—and electrical conductivity—the path to carry high currents. Though the electrical path has been worked on for many years with more or less success, the thermal path has always been the main challenge.

Besides the need for high thermal and electrical conductivity, power semiconductors need to be isolated from the rest of the environment because they carry high voltages; this is a safety requirement. Voltage isolation barriers (like DBC substrates) usually demonstrate poor thermal conductivity. Common isolation barriers like high thermal conductivity compounds exhibit 2 to 5 W/mK thermal conductivity. State of the art oxides such as Aluminum Oxide (Al2O3) show a 24 to 28 W/mK thermal conductivity. More modern Aluminum Nitride (AlN) realistically offers 150 to 180 W/mK thermal conductivity. Therefore, with these materials there is a substantial undesirable thermal difference in between the semiconductor junction temperature (Tj) and the cooling mechanism (usually liquid glycol) at the thickness required to ensure electrical isolation.

Power semiconductors such as Silicon Insulated Gate Bipolar Transistors (Si IGBTs) and Silicon Carbide metal oxide semiconductor field effect transistors (SiC MOSFETs) have the same electrical and thermal path through their bottom side unlike other power dissipating devices such as MCU, logic, memory and DSP chips. Today's most common solution to ensure electrical insulation, and high current carrying capability for Si IGBT and SiC MOSFETs are Direct Bonded Copper (DBC) substrates. Unfortunately, they do not provide high heat carrying capacity.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIGS. 1A-1C depict thermal profiles and a side schematics view of different wafer types showing the General Impact of Adding Diamond to Power Electronics in prior art implementations.

FIG. 2 depicts a cross section view of a prior art electrical/thermal path in a power device.

FIG. 3A is a thermal impedance Rth model representation of the prior art electrical/thermal path in a power device.

FIG. 3B is a table containing relevant values for calculation of the thermal impedance for an example prior art electrical/thermal path in the power device.

FIG. 4A is a line graph showing the normalized on-resistance (RdsON) versus temperature of a typical Silicon Carbide (SiC) power device.

FIG. 4B is a line graph depicting the saturation voltage across the collector and emitter (V_{CE(sat)}) vs temperature for a typical IGBT device.

FIG. 5 is a table summarizing power conduction losses for a 3-phase 250 KW inverter system translated into a standard EV sedan range according to current power device standards

FIG. 6 is cross section view of the improved Thermal-Electrical path power devices according to aspects of the present disclosure.

FIG. 7 is a thermal impedance (Rth) model representation of the improved electrical/thermal path power device according to aspects of the present disclosure.

FIG. 8 is a table containing relevant values for calculation of the thermal impedance for an example improved electrical/thermal path power device.

FIG. 9 is a view of a metal base substrate used in the fabrication of single crystal diamond substrates for silicon transistors according to aspects of the present disclosure

FIG. 10 is a view showing the alignment of the metal base substrate on a metal base substrate assembly during fabrication of single crystal diamond substrates for silicon transistors according to aspects of the present disclosure.

FIG. 11 is a view depicting placement of a first stencil and placement sintering paste the metal base substrate during fabrication of single crystal diamond substrates for silicon transistors according to aspects of the present disclosure.

FIG. 12 is a view showing a single crystal diamond wafer being added on top of the sintering paste during fabrication of single crystal diamond substrates for silicon transistors according to aspects of the present disclosure.

FIG. 13 is a view depicting placement of a second stencil and a second layer of sintering paste and applied over top the single crystal diamond wafer during fabrication of single crystal diamond substrates for silicon transistors according to aspects of the present disclosure.

FIG. 14 is view showing placement of a thin metal layer on top of the second sintering paste layer a single crystal diamond wafer during fabrication of single crystal diamond substrates for silicon transistors according to aspects of the present disclosure.

FIG. 15 is a view depicting sintering the assembly stack using a sintering press during fabrication of single crystal diamond substrates for silicon transistors according to aspects of the present disclosure

FIG. 16 is a view showing removal of the sintering press and sintering dye leaving a completed SCD component during fabrication of single crystal diamond substrates for silicon transistors according to aspects of the present disclosure.

FIG. 17 is a view depicting removal of the SCD component from the dum bars during fabrication of single crystal diamond substrates for silicon transistors according to aspects of the present disclosure.

FIG. 18 is a view showing etching of a SCD component during fabrication of a device package according to aspects of the present disclosure.

FIG. 19 is a view depicting removal of the SCD component from the dum bars and application of sintering paste during fabrication of a device package according to aspects of the present disclosure.

FIG. 20 is a view showing sintering of metal bus bars to the SCD component during fabrication of a device package according to aspects of the present disclosure.

FIG. 21 is a view showing the silicon devices sintered to the SCD component during fabrication of a device package according to aspects of the present disclosure

FIG. 22 is a view depicting bond wires conductive coupling the silicon devices to the metal bus bars during fabrication of a device package according to aspects of the present disclosure.

FIG. 23 is a view showing potting die formed to fit the SCD component, bus bars and silicon device assembly during fabrication of a device package according to aspects of the present disclosure.

FIG. 24 is a view depicting the SCD component, bus bars and silicon device assembly placed in the potting die and aligned via alignment pets in the potting die during fabrication of a device package according to aspects of the present disclosure.

FIG. 25 is a view showing the finished potted device package according to aspects of the present disclosure.

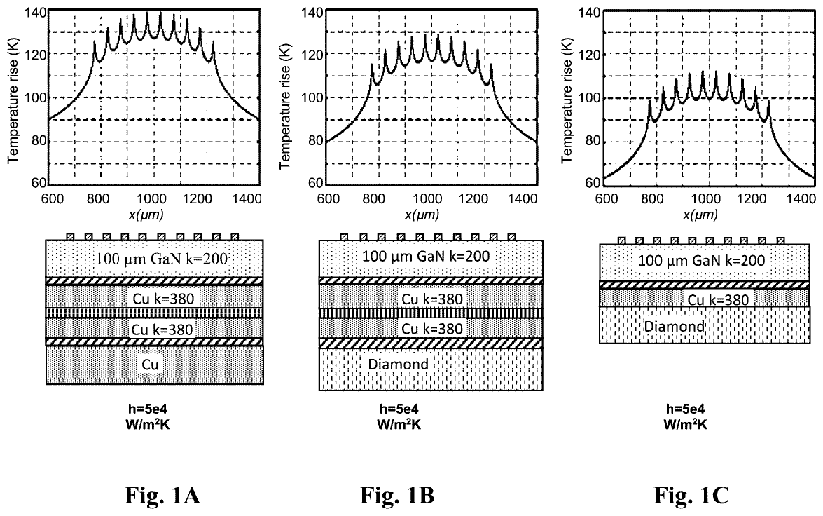

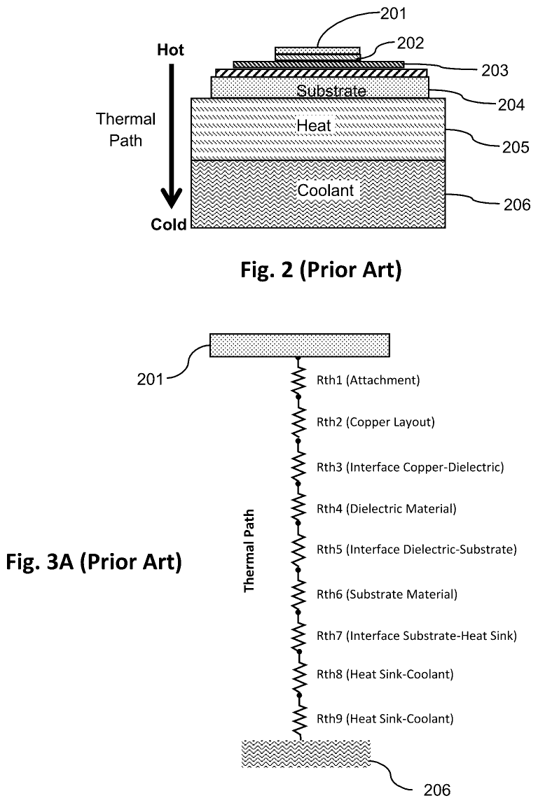

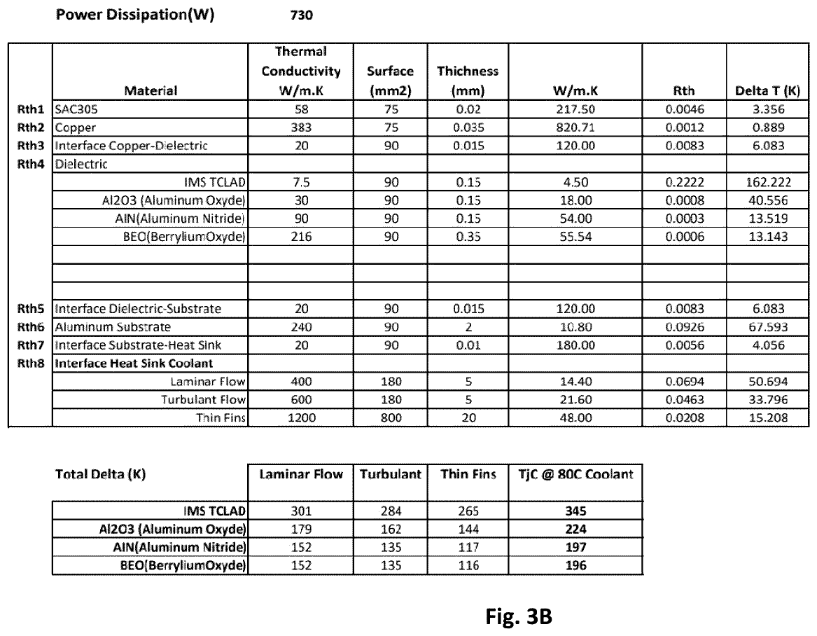

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the exemplary embodiments of the invention described below are set forth without any loss of generality to, and without imposing limitations upon, the claimed invention.

### Introduction

### Overview

Electronic vehicle (EV) power electronics has increasingly become heat dissipation limited, and the potential range of electronics architectures has been limited by available materials. The thermal stress induced into power semiconductor switches has been difficult for semiconductor and inverter companies. Engineers across the entire industry have been stuck using materials in their electronics design that do not truly meet the characteristics required for advancing EV power electronics, such in particular including a material that combines extreme thermal conductivity with extreme voltage insulation.

Single-crystal diamond (SCD) is a most extreme material—in multiple dimensions and by a decisive factor each—in particular through its combination of extreme thermal conductivity and extreme electrical insulation. SCD exhibits remarkable dielectric properties including a low dielectric constant of 5.7, a loss tangent below 0.0001 at 35 GHz and a high dielectric strength of 10 MV/cm. This means 20 μm (2×10⁻⁵ m) of SCD can insulate 20 kV while at the same time delivering thermal conductivity as high as 3,000 W/mK.

Diamond Foundry, Inc. of South San Francisco, California has achieved production of single-crystal diamond in wafer dimensions covering the die sizes required by commercially relevant computer and power-electronics chips.

### The Power Traction Inverter Dilemma

An EV's Power Traction Inverter (PTI) is a critical element of electric mobility. Because of their level of complexity, electrical and thermal stress and cost, PTIs have always been one of the weakest links of the electric mobility implementation, with a remarkable level of failure on the early development of this emerging market, and certainly a technological barrier of entry for OEM adoption. Driving conditions and style often induce substantial electrical and thermal stress to the active components of the inverter and their surrounding elements and if not properly addressed leads to drastic life reduction and eventually failures of the system.

Power inverter advancement has been slow and incremental due to complex design and manufacturing aggravated by custom subsystems requirements, sophisticated integration of high-power electronics, material science, mechatronics, and thermal management. Power density is certainly the key metric of performance for modern power inverters underscoring technology and efficiency. As a reference, state-of-the-art designs exhibit 33 kW/L (Tesla Model 3 is 12L, 4.8 kg, 400 kW) and 36 kW/L (Audi e-Tron is 5.5L, 8 kg, 200 kW).

Power semiconductors are essentially driven by two factors: Thermal conductivity—the path to cool them down—and electrical conductivity—the path to carry high currents. Though the electrical path has been worked on for many years with more or less success, the thermal path has always been the main challenge.

Besides the need for high thermal and electrical conductivity, power semiconductors need to be electrically isolated from the rest of the environment because they carry high voltages; this is a safety requirement. Unfortunately, voltage isolation barriers (like DBC substrates) usually demonstrate poor thermal conductivity. Common isolation barriers like high thermal conductivity compounds exhibit 2 to 5 W/mK, state of the art oxides such as Aluminum Oxide (Al2O3) show a 24 to 28 W/mK, more modern Aluminum Nitride (AlN) realistically offer 150 to 180 W/mK, therefore keeping a substantial undesirable thermal difference in between the semiconductor junction temperature (Tj) and the cooling mechanism (usually liquid glycol) at the thickness required to ensure electrical isolation.

Power semiconductors such as Silicon Insulated Gate Bipolar Transistors (Si IGBTs) and Silicon Carbide metal oxide semiconductor field effect transistors (SiC MOSFETs) have the same electrical and thermal path through their bottom side unlike other power dissipating devices such as MCU, logic, memory and DSP chips. Today's most common solution to ensure electrical insulation, and high current carrying capability for Si IGBT and SiC MOSFETs are Direct Bonded Copper (DBC) substrates. Unfortunately, they do not provide high heat carrying capacity.

### Diamond Based Power Electronics

Because of its remarkable properties, diamond and diamond based solutions have always been on the far reaching scope of power semiconductors developers. Some would call it the “Holy Grail” for semiconductors applications in nature that it exhibits ultra-high thermal conductivity and ultra-high band gap. Unlike graphene (another allotrope of carbon) which is electrically conductive, diamond is a premium isolator. Diamond Foundry now offers a practical and cost affordable solution to a very old issue: How to implement a cool down path efficiently to a power semiconductor and insure dielectric isolation at the same time.

The advantages of diamond have long been well-known, indeed this not being any surprise or novelty. What is new and disruptive is that Diamond Foundry has now managed to: a) produce high-quality single-crystal diamond wafers for all chip die sizes; b) drive down cost to the levels required by automotive power electronics; and c. novel power electronics architectures that fully utilize the capabilities of novel diamond wafers.

Prior work by our team as well as other groups has shown that diamonds reduce peak temperature by as much as 20% for various semiconductors, such reduction improving power efficiency by 10% during such periods.

SCD wafers can be used close to the switching semiconductor device junction in multiple ways: replace ceramics (e.g., Aluminum Oxide (Al₂O₃), Aluminum Nitride (AlN), Silicon Nitride (Si₃N₄)) in direct-bonded-copper (DBC) substrates; replace heat spreaders in novel discrete packages; allow for thinning the semiconductor wafer. SCD wafers allow inverter size, weight, and cost reductions based on any and all semiconductor technologies, not requiring a “bet” on a novel form of a semiconductor gaining commercial traction.

### The Importance of Sustaining a Lower Junction Temperature

The thermal stress induced into power semiconductor switches yields failure as well as energy efficiency loss. As a general rule of thumb, every 10° C. increase in temperature reduces the semiconductor life expectancy by half, setting for example the trend to higher-temperature resilient silicon designs to 200 C from 175 C for Silicon Carbide power switches.

Unlike IGBTs who have an almost constant V_{ce(Sat)} versus temperature coefficient, MOSFET's (including SiC) RdsON is a Positive Temperature Depending Parameter (TDP) which means that RdsON increases with temperature.

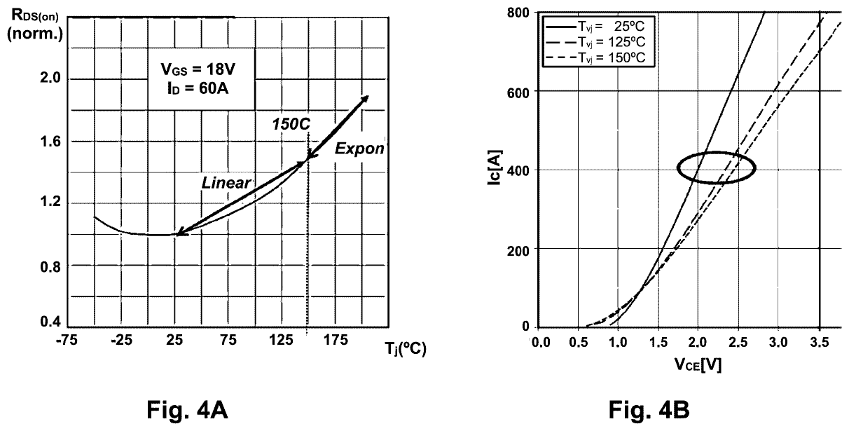

FIG. 4A shows a normalized RdsON for a common SiC device. As the typical RdsON is specified at 25 C to be 1 (e.g., 7 mOhm) it increases 45% (10.39 mOhm) at 150 C, 64% (11.64 mOhm) at 175 C and 90% (12.87 mOh) at 200 C. The growth of RdsON versus Tj is split into the linear (25 to 150 C) and the exponential region (150 to 200 C) meaning that for the same amount of current (400 A), the power conduction losses will be 1120 W at 25 C, 1359 W at 100 C, 1662 W at 150 C, 1863 W at 175 C and 2060 W at 200 C.

FIG. 4B shows the V_{ce(sat)} for a typical modern IGBT. Conduction losses at 400 A establishes at 800 W at 25 C, 920 W at 125 C and 1000 W at 150 C (no further data available). At the EV's inverter frequency operation (e.g., 15 kHz), conduction losses represent about 60% of the cumulated conduction-switching losses of the device. This is mainly due to the so called “tail effect” of IGBTs and it is directly related to the surface area of the silicon chip, the greater the surface, the bigger the switching losses. Total cumulated conduction and switching losses for IGBTs establishes then to 1375 W at 25 C, 1580 W at 125 C and 1720 W at 150 C. It is remarkable that despite a very slim efficiency advantage to SiC versus IGBTs, the trend of adoption towards SiC appears irreversible with even the predominant cost of SiC versus IGBTs (about 5×) underscoring that implementation cost is undermined in favor of performance and EV's range gain.

Since EV's onboard coolant temperature is typically set to be 80° C. as a standard, the challenge here is to keep the Tj as close as possible to coolant to eliminate the unnecessary conduction losses induced by the Tj in the exponential region and part of the linear region too for SiC and allow for a die surface area reduction for IGBTs. Bipolar structures such as IGBTs are quite resilient in respect of forward current as long as temperature dependent latch-up conditions are not triggered. It is generally admitted that current density of up to 1000 A/cm² set the limit and IGBTs manufacturer stay usually within 80% to 90% of this limit over the temperature range. Mastering the junction temperature for IGBTs under the latch-up condition enables a substantial die size active area reduction proportionately impacting the switching losses that IGBTs have been suffering since inception. Properly applied thermal management solutions such as Diamond Foundry solutions could see the equalization of modern SiC and antique IGBTs technologies for E-Mobility frequency switching range (10-20 kHz) at one fifth of the cost.

### Specific Impact on EV Driving Range

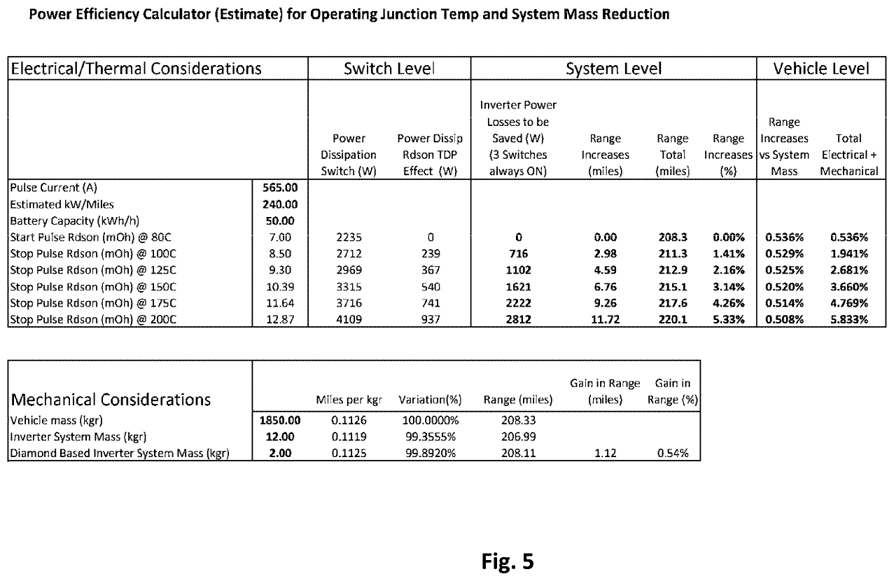

FIG. 5 summarizes the power conduction losses for a 3-phase 250 KW inverter system translated into a standard EV sedan range according to nowadays standards. The 400 A per phase current (565 A peak) induced losses are studied across 80 C (coolant) to 200 C Tj.

The “Inverter Power Losses to be Saved” column shows the energy to be saved from the battery at various Tj, and the range is calculated accordingly from the battery capacity. Assuming the power switches Tj can be kept near by the coolant temperature (80 C) the total power losses saving could reach up to 2812 W per battery charge or 11.72 miles or 5.33% range increase.

This study is conservative in that it does not take into consideration the regenerative power saving which is estimated to be 15-20% of these figures. This includes power losses temperature dependency in Fast Recovery Diodes (FRD) associated to IGBTs, thermal dependency losses of the SiC MOSFET intrinsic diodes (which exhibit poor performances vs temperature) and the reduction of associated circuitry such as gate driver and collateral components. Size reduction in such proportion opens the possibility of a directly integrated inverter-motor eradicating power losses in cables length and terminals, accounting for another few fractions of percent of the battery capacity.

### Single-Form Factor Architecture for EV Power Electronics

Combining the extraordinary thermal-conductivity, voltage-insulation, and wafer-finish properties of single-crystal diamond wafers, now available from Diamond Foundry, novel device and system designs as well as more efficient assembly processes are enabled that the industry has not yet had the opportunity to pursue for GaN, SiC and IGBTs silicon chips.

In particular, Diamond Foundry's SCD wafer enables single-form-factor power inverters to exceed 1000 kW/L (e.g., 400 kW for a 0.4L system). This comes with a greater system efficiency, losses and system cost reduction translating into energy saving and electric mobility range extension.

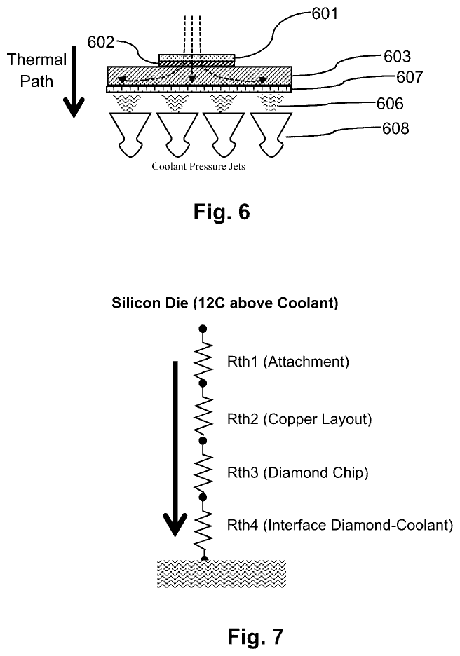

A novel thermal management configuration according to aspects of the present disclosure is shown in FIG. 6. This configuration delivers a drastic reduction of the thermal impedance elements from nine to four elements. In this configuration, a semiconductor die 601 is attached to a copper substrate 603 by a silver attachment 602. The copper substrate 602 is diffusion bonded to a SCD wafer 607. Diffusion processes used for attachment in between the simplified number of elements constituting the thermal path are now reduced to nanometer scale insuring a free thermal propagation from the semiconductor die 1 through the diamond chip 607 to the coolant 606. The use of the SCD wafer 607 allows for a more three-dimensional thermal propagation, as indicated by the dashed arrows.

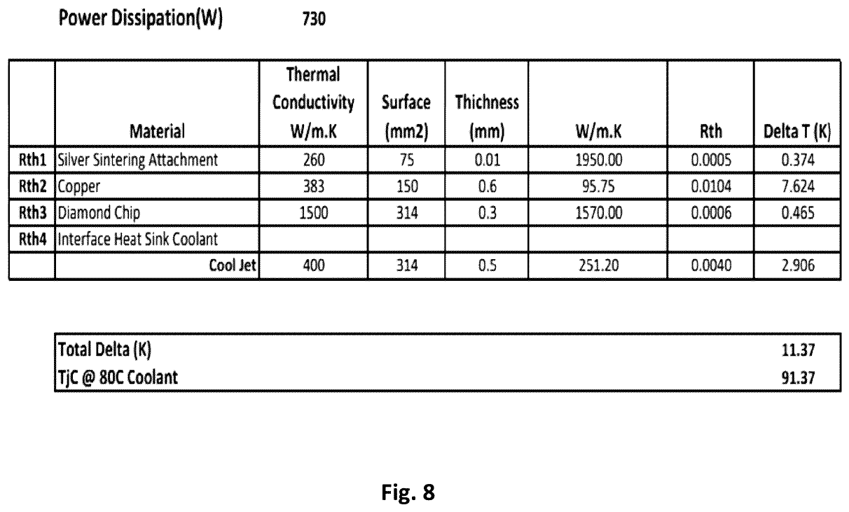

One or more pressurized coolant jets 608 deliver coolant 606 to the exposed surface of the diamond wafer 607, offering a perpendicular-impact flow yielding greater performance than laminar, turbulent, or turbulent “thin fins” solution. The corresponding thermal impedance model depicted in FIG. 7 in the table depicted and FIG. 8 summarize these advantages.

Because the dramatic reduction of total Rth (0.0155 compared to a state of the art value of ˜0.11) the silicon die Tj is now intimately related to the coolant temperature in a lockdown position creating a Tj “clamp” at around 12° C. above the coolant enabling significant saving in conduction losses compared to those described with respect to FIG. 5, optimization of mechanical geometries for the inverter design and the reduction of needed active silicon die surface.

The advanced material and thermal management technology of a configuration like that of FIG. 6 offers a drastic reduction in thermal impedance and inverter size reduction paving the way to substantial EV range extension, cost reduction and extreme reliability. Furthermore, this technology is scalable and adaptable to similar markets where high power efficiency and reliability is mission critical (i.e. power generation, charging station, grid balancing etc. . . . ).

### Fabrication of A Single Crystal Diamond substrate for Silicon Transistors

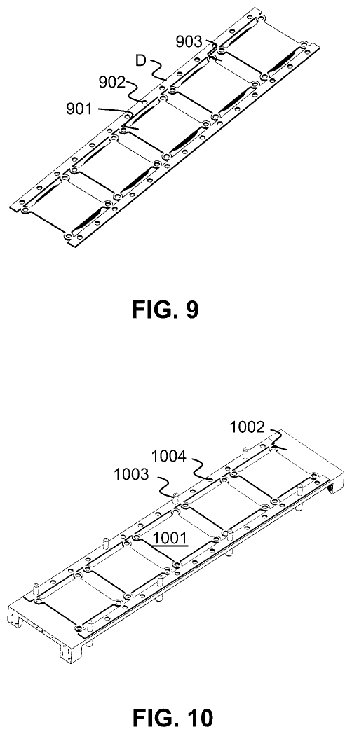

A single crystal diamond substrate for silicon devices may improve thermal conduction. Formation of the single crystal diamond substrate starts with a metal substrate 901 such as the one shown in FIG. 9. The metal substrate 901 may be any suitable metal or metal alloy such as copper, aluminum, silver, gold, nickel or iron. As shown the metal substrate may be included in a fabrication assembly that has alignment holes 902 along dum bars D that may be used to fabricate multiple copper substrates 901 at one time. A cutout 903 separates each metal substrate 901 to case separation. By way of example, the metal substrate may be made of copper 0.590 mm to 1 mm thick and more preferably 0.6 mm thick

As seen in FIG. 10 the metal substrate assembly 1001 may be fitted to an assembly die 1002. The assembly die 1002 may include alignment pegs 1003. Each alignment peg 1003 may be configured to fit into an alignment hole 1004 of the metal substrate assembly 1001.

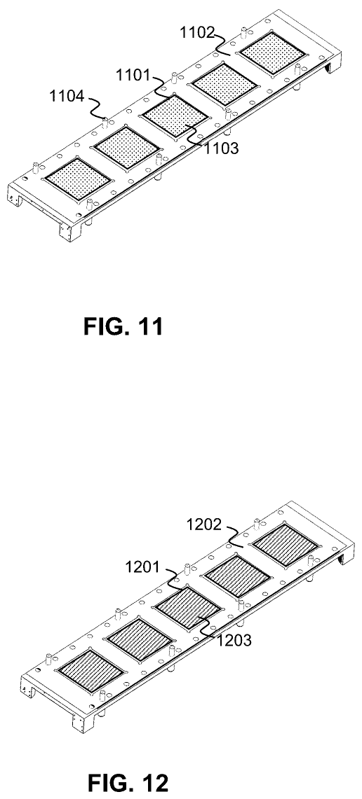

FIG. 11 shows that a first stencil 1102 may be added over top the metal substrate 1101 to aid in application of a first layer of sintering paste 1103. The sintering paste 1103 generally includes metal particles in a binder. By way of example, and not by way of limitation, the sintering paste 1103 may be a silver sintering paste. The alignment pegs 1104 aid in aligning the stencil with the metal substrate and using the alignment holes also present in the stencil 1102. The first stencil 1102 ensures that the first layer of sintering paste 303 is properly located on the substrate 1101. The first layer of sintering paste 1103 may be between 70-90 Micrometers thick before sintering.

In FIG. 12 a single crystal diamond wafer (SCD) 1203 is added on top of the first layer of sintering paste 1103. The first stencil 1202 ensures that the SCD 1203 is properly aligned on top of the sintering paste and the metal substrate 1201. The SCD may be between 50 and 1000 micrometers (5×10⁵ m to 1×10⁻³ m) thick and is preferably 300 micrometers (3×10⁻⁴ m) in thickness. In one implementation, the SCD wafer may be 18 millimeters long by 18 millimeters (1.8×10⁻² m by 1.8×10⁻² m) wide.

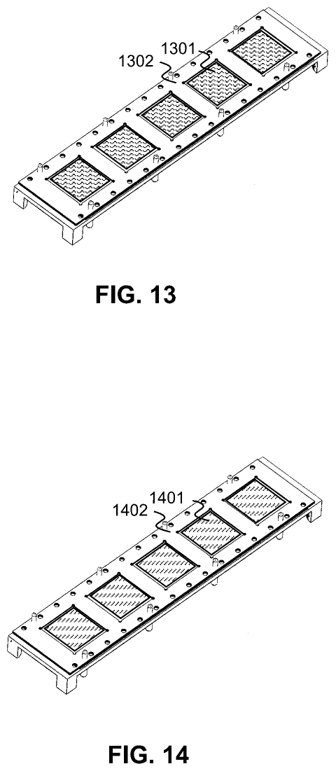

Next, as depicted in FIG. 13, a second layer of sintering paste 1301 is applied over top the SCD layer using the first stencil to align application. Next a second stencil 1302 is placed overtop the first stencil and aligned using the alignment pegs. The second layer of sintering paste 1301 may be between 70 and 90 Micrometers thick.

A thin metallic layout layer 1401 is applied on top of the second layer of sintering paste creating an SCD component assembly stack as shown in FIG. 14. The thin metallic layout layer may be for example and without limitation composed of a thin layer of copper, gold, silver or aluminum. The second template 1402 aligns the thin metallic layout layer 1401 to the proper orientation over the second layer of sintering paste. The thin metallic layout layer may be 30-300 micrometers (3×10⁻⁵-3×10⁻⁴ m) thick with +/− 0.1% variation and is nominally 100 micrometers (1×10⁴ m) thick with +/− 0.1% variation.

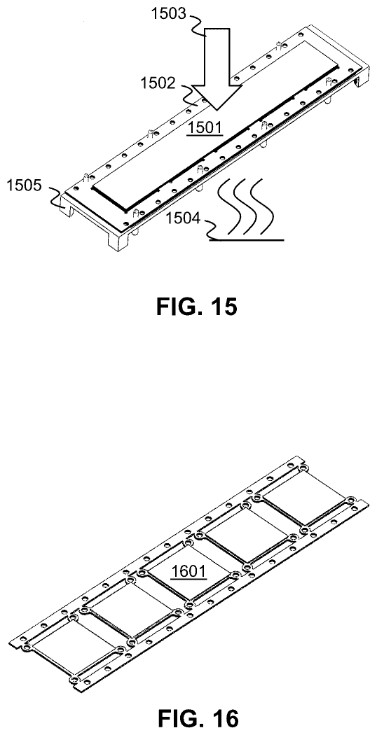

As shown in FIG. 15, a sinter press insert 1501 is placed over the thin metallic layout layer and the second stencil 1502. The sinter press insert 1501 includes protrusions configured to fit into the holes in the second stencil 1502. The protrusions are configured to lie flat against the thin metallic layout layer in the holes of the second stencil 1502. The sinter press insert 1501 also includes cut-out regions to accommodate second stencil 1502 when the force is applied to the sinter press insert and the protrusions press in to the holes of the second stencil 1502.

Next, the assembly stack is sintered. Pressure 1503 is applied to the sinter press insert and the assembly die 1505. While pressure is being applied 1503 the whole assembly is heated 1504 at pressure, temperature and time sufficient to bond the sintering paste to the thin metallic layout layer and the SCD layer and the metal substrate to the SCD layer. In one example implementation, pressure applied between the sinter press insert 1501 to the assembly die 1501 may be around 16 mega Pascals while heated sinter-press platers at 230 degrees Celsius heat the assembly for 6 minutes. Following the application pressure and heat, the sintering paste should be bonded to the SCD layer and the metal substrate layer and the thin metallic layout layer. The final thickness of each of the sintering paste layers may be around 6-10 micrometers.

Finally, as depicted in FIG. 16, the sinter press insert, stencils and assembly die are removed leaving the completed SCD substrate component 1601. Multiple SCD substrate components may be fabricated at one time using dum bars with holes for alignment.

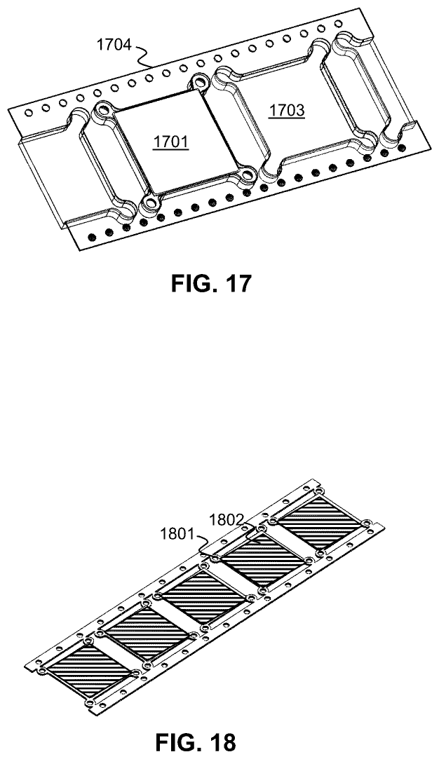

FIG. 17 shows that after sintering and removal of the assembly die, each SCD substrate component may be removed from the dum bars. Removal of the SCD substrate component from the dum bars may be accomplished by any removal means such as cutting or stamping. As shown, some implementations of the SCD substrate component may be fabricated without dum bars and instead the assembly die 1704 includes cutout 1703 for alignment of the copper substrate layer to the assembly die 1704.

### SCD Substrate Component Integrated Device Package

The SCD substrate components may be further integrated into a silicon device package to provide improved cooling for the silicon device. As shown in FIG. 18 the SCD substrate components 1801 may be masked 1802 on the thin metallic layout layer with an etching mask patterned for coupling the SCD substrate component to a semi-conductor device. The etching mask may be any etch masking material known in the art such as a photolithographic mask, mechanically applied mask or the like. The SCD substrate components 1801 having the patterned masks 1802 may then be etched. The etchant may be selective for the thin metallic layout layer on the surface of the SCD substrate device for example and without limitation ferric chloride, nitric acid, hydrochloric acid or aluminum hydroxide.

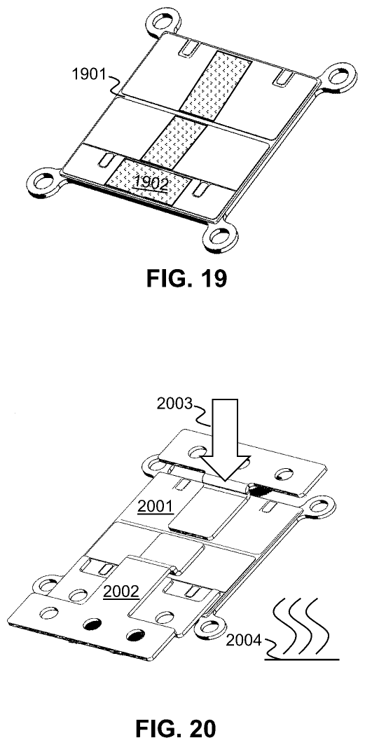

FIG. 19 depicts that the etched SCD component device 1901 may be removed from the dum bars and prepared for integration into a device package. Sintering paste 1902 may be spread in areas on the etched surface of the component device.

Metal bus bars 2002 are placed over the sintering paste on the etched surface of the SCD component device 2001 as shown in FIG. 20. Sufficient pressure 2003 and heat 2004 are applied to the bus bar and SCD component assembly for time sufficient to sinter the bus bars to the SCD component device using the sintering paste. For example and without limitation to sinter the device the bus bars and the SCD component may have around 16 mega pascals of pressure applied to them through a heated vice or heated press at 230 degrees Celsius for 6 minutes. Once complete the metal bus bars 2002 may be bonded to the etched surface of the SCD component device 2001.

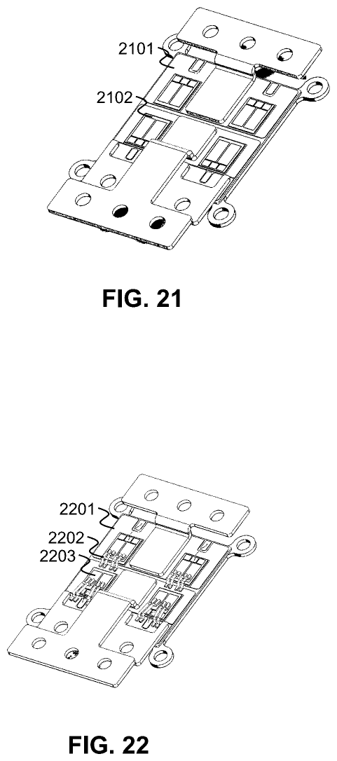

Next, as shown in FIG. 21, one or more silicon devices 2102 such as, for example and without limitation, MOSFETs, Integrated gate bipolar transistors, resistors, diodes, or other types of transistors may be sintered to the etched surface of the SCD component 2101. The silicon devices 2102 may be placed over a sintering paste, such as silver sintering paste, applied to the etched surface of the SCD component 2101. As shown, multiple silicon devices 2102 may be sintered to the surface of the SCD component at a time, pressure and heat sufficient to bond the sintering paste to the silicon devices and the etched surface of the SCD component. For example and without limitation, to sinter the silicon devices to the SCD component around 16 mega pascals of pressure may be applied to the silicon device and SCD component through a vice or press while heating in an oven at 230 degrees Celsius for 6 minutes.

Bond wires 2202 may then be formed, attaching the silicon devices 2203 to a portion of the SCD component 2201 as depicted in FIG. 22. The bond wires 2202 may be formed by any known method such as, for example and without limitation ball bonding, wedge bonding or compliant bonding.

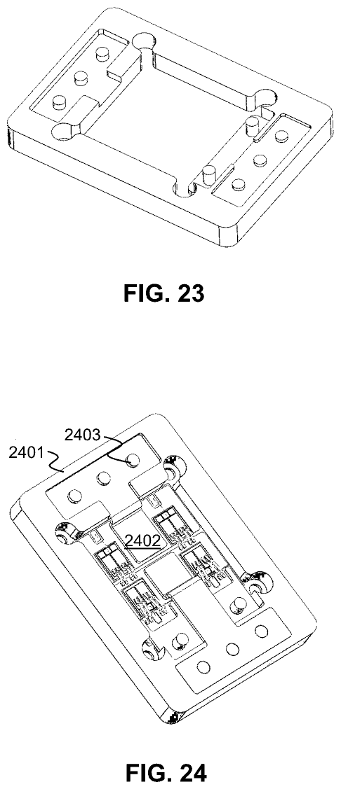

As shown in FIG. 23 a potting die may be created to fit the SCD substrate component integrated assembly. The potting die may include several alignment pins to locate the SCD substrate component integrated assembly properly into the potting dye. The alignment pins may fit into screw holes or other alignment holes in the SCD component or the bus bars.

The SCD substrate component integrated assembly 2402 is then placed into the potting die 2401 using the alignment pins 2403 to ensure proper placement as depicted in FIG. 24. Potting compound solution is poured on top of the SCD substrate component integrated assembly and allowed to cure. The compound solution may be for example and without limitation epoxy potting compound, silicone potting compound, urethane potting compound, polyacrylate potting compound, potting gel or the like.

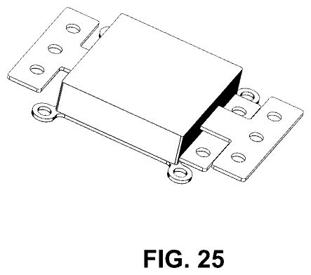

Once the potting compound has cured the SCD substrate component integrated device as shown in FIG. 25 may be removed from the potting die. The SCD substrate component integrated device is complete and may be used in other devices. The SCD substrate allows for excellent cooling of the integrated device as the single crystal diamond provides exceptional thermal conduction and the small cross section created through sintering allows for further improved thermal coupling.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A method for manufacturing an electronic component, comprising:
forming a stack having a metallic substrate, a single crystal diamond (SCD) wafer, and a metallic layout layer, wherein the metallic layer is thinner than the metallic substrate; and
subjecting the stack to heat and pressure for a sufficient time to bond the metallic layout layer to the SCD wafer and the SCD wafer to the substrate.

2. The method of claim 1, wherein the metallic substrate is made of copper.

3. The method of claim 1, wherein the metallic layout layer is made of copper.

4. The method of claim 1, wherein the metallic substrate and the metallic layout layer are both made of copper.

5. The method of claim 1, wherein the stack includes a layer of metal sintering paste between the metallic substrate and the SCD wafer.

6. The method of claim 5, wherein the layer of metal sintering paste includes a silver paste.

7. The method of claim 1, wherein the stack includes a layer of metal sintering paste between the SCD wafer and the metallic layout layer.

8. The method of claim 7, wherein the layer of metal sintering paste includes a silver paste.

9. The method of claim 1, wherein the stack includes a first layer of metal sintering paste between the metallic substrate and the SCD wafer and a second layer of metal sintering paste between the SCD wafer and the metallic layout layer.

10. The method of claim 9, wherein the first and second layers of metal sintering paste both include silver sintering paste.

11. The method of claim 9, wherein the metallic substrate and the metallic layout layer are both made of copper and wherein the first and second layers of metal sintering paste both include silver sintering paste.

12. An electronic component at an intermediate stage of manufacture, comprising:
a stack having a metallic substrate, a single crystal diamond (SCD) wafer, and a metallic layout layer, wherein the metallic layer is thinner than the metallic substrate.

13. The electronic component of claim 9, wherein the substrate is made of copper.

14. The electronic component of claim 10, wherein the metallic substrate is between about 0.5 mm and about 1 mm thick.

15. The electronic component of claim 9, wherein the metallic layout layer is made of copper.

16. The electronic component of claim 12, wherein the metallic layout layer is about 30 μm to about 300 μm thick.

17. The electronic component of claim 9, wherein the metallic substrate and the metallic layout layer are both made of copper.

18. The electronic component of claim 12, wherein the SCD wafer is about 50 μm to 1000 μm thick.

19. The electronic component of claim 18 wherein the SCD wafer is about 18 mm long by about 18 mm wide.

20. An electronic component, comprising:
a stack having a metallic substrate, a single crystal diamond (SCD) wafer, and a metallic layout layer, a first sintered metal layer forming a bond between the substrate and the SCD wafer, and a second sintered metal layer forming a bond between the SCD wafer and the metallic layer, wherein the metallic layout layer is thinner than the metallic substrate.

21. The electronic component of claim 20, wherein the substrate is made of copper.

22. The electronic component of claim 21, wherein the metallic substrate is between about 0.5 mm and about 1 mm thick.

23. The electronic component of claim 20, wherein the metallic layout layer is made of copper.

24. The electronic component of claim 23, wherein the metallic layout layer is about 30 μm to about 300 μm thick.

25. The electronic component of claim 20, wherein the metallic substrate and the metallic layout layer are both made of copper.

26. The electronic component of claim 21, wherein the first sintered metal layer includes silver.

27. The electronic component of claim 26, wherein the first sintered metal layer is about 6 μm to about 10 μm thick.

28. The electronic component of claim 20, wherein the second sintered metal layer includes silver.

29. The electronic component of claim 28, wherein the second sintered metal layer is about 6 μm to about 10 μm thick.

30. The electronic component of claim 20, wherein the first and second sintered metal layers include silver.

31. The electronic component of claim 20, wherein the metallic substrate and the metallic layer are both made of copper and wherein the first and second sintered metal layers both include silver.

32. The electronic component of claim 20, wherein the SCD wafer is about 50 μm to 1000 μm thick.

33. The electronic component of claim 32 wherein the SCD wafer is about 18 mm long by about 18 mm wide.
